(19) United States
(12) Patent Application Publication
(10) Pub. No.: US 2024/0321807 A1
(43) Pub. Date: Sep. 26, 2024

(54) BARRIER DISPENSING COMBINED WITH NON-CONDUCTIVE PASTE TO ENABLE PACKAGES WITH RESTRICTED UNDERFILL AREAS

(71) Applicant: Intel Corporation, Santa Clara, CA (US)

(72) Inventors: Jonas CROISSANT, Hillsboro, OR (US); Xavier F. BRUN, Chandler, AZ (US); Gustavo BELTRAN, Chandler, AZ (US); Roberto SERNA, Chandler, AZ (US); Ye Seul NAM, Chandler, AZ (US); Timothy GOSSELIN, Phoenix, AZ (US); Jesus S. NIETO PESCADOR, Chandler, AZ (US); Dingying David XU, Chandler, AZ (US); John C. DECKER, Tempe, AZ (US); Ifeanyi OKAFOR, Gilbert, AZ (US); Yiqun BAI, Chandler, AZ (US)

(21) Appl. No.: 18/123,838

(22) Filed: Mar. 20, 2023

(51) Int. Cl. H01L 23/00; H01L 25/16

(52) U.S. Cl. CPC H01L 24/32; H01L 25/167; H01L 24/16; H01L 24/73; H01L 2224/16145; H01L 2224/26145; H01L 2224/32145; H01L 2224/73204

(57) ABSTRACT

Embodiments disclosed herein include multi-die modules. In an embodiment, the multi-die module comprises a first die and a second die coupled to the first die. In an embodiment, the second die comprises a keep out zone that at least partially overlaps the first die. The multi-die module may further comprise an underfill between the first die and the second die. In an embodiment, the underfill is entirely outside the keep out zone, and an edge of the underfill facing the keep out zone is non-vertical.

### TECHNICAL FIELD

Embodiments of the present disclosure relate to electronic systems, and more particularly to electronic packages with underfill keep out zones that are protected by a barrier.

### BACKGROUND

In optical packaging applications, a photonics integrated circuit (PIC) is coupled to an electrical integrated circuit (EIC). Typically, a laser is used by the PIC to send communication signals out of the system and an optical sensor receives signals. The PIC functions to convert optical signals to electrical signals that can be used by the EIC. Conversely, electrical signals from the EIC are converted to optical signals by the PIC for transmission. In particular, the laser is very sensitive to changes in environmental conditions. As such, the space between the EIC and PIC proximate to the laser needs to be voided. At the same time, bumps between the EIC and the PIC need to be surrounded with an underfill for reliability purposes. Accordingly, a keep out zone (KOZ) is needed within the footprint of the PIC and the EIC. This is difficult to implement, because traditional underfill technologies (e.g., capillary underfill (CUF)) do not provide easy ways to maintain the KOZ.

CUF solutions that leverage a barrier have been proposed. However, the barrier needs to be one hundred percent leak proof, as even small gaps will generate massive CUF leaks into the KOZ. Small gaps are expected since the PIC bonding is not precisely controlled. If the barrier is too short, leaks will occur. Alternatively, if the barrier is too tall, interconnects between the PIC and the EIC may not be properly formed. Another proposed solution is to use thermo-compression of a non-conductive film (TC-NCF). However, such film approaches cover the whole wafer and does not have selective underfill capabilities to restrict flow into the KOZ. The same applies to mold underfill (MUF) methods. Non-conductive paste (NCP) solutions are also limited due to potential KOZ violations, and reliability risks (e.g., NCP oozing out and causing voids).

### BRIEF DESCRIPTION OF THE DRAWINGS

FIG. 1A is a plan view illustration of a photonics integrated circuit (PIC) with keep out zones (KOZs), in accordance with an embodiment.

FIG. 1B is a plan view illustration of a photonics module that includes a PIC mounted to an electrical integrated circuit (EIC), where the KOZ is provided over the EIC, in accordance with an embodiment.

FIG. 2 is a cross-sectional illustration of a photonics module that includes barriers to confine the flow of a non-conductive paste (NCP), in accordance with an embodiment.

FIG. 3A is a cross-sectional illustration showing the profile of the barrier and the conformal nature of the NCP, in accordance with an embodiment.

FIG. 3B is a cross-sectional illustration of the NCP after the barrier is removed, in accordance with an embodiment.

FIG. 4 is a plan view illustration of an EIC that illustrates the location of bump fields relative to the KOZ, in accordance with an embodiment.

FIG. 5A is a plan view illustration of an EIC, in accordance with an embodiment.

FIG. 5B is a plan view illustration of the EIC after a barrier is applied, in accordance with an embodiment.

FIG. 5C is a plan view illustration of the EIC after an NCP is applied, in accordance with an embodiment.

FIG. 5D is a plan view illustration of the EIC after a PIC is bonded with a thermocompression bonding (TCB) process, in accordance with an embodiment.

FIG. 6A is a plan view illustration of an EIC with ring type barriers, in accordance with an embodiment.

FIG. 6B is a plan view illustration of an EIC with C-shaped barriers, in accordance with an embodiment.

FIG. 6C is a plan view illustration of an EIC with line type barriers, in accordance with an embodiment.

FIG. 6D is a plan view illustration of an EIC with a pair of line type barriers on two sides of the KOZ, in accordance with an embodiment.

FIG. 6E is a plan view illustration of an EIC with a ring type barrier around a perimeter of the KOZ, in accordance with an embodiment.

FIG. 6F is a plan view illustration of an EIC with a ring type barrier with gaps, in accordance with an embodiment.

FIG. 6G is a plan view illustration of an EIC with C-shaped barriers that face each other and are offset, in accordance with an embodiment.

FIG. 7 is a cross-sectional illustration of an electronic system with a photonics module that includes barriers to confine the flow of an NCP to maintain a KOZ, in accordance with an embodiment.

FIG. 8 is a schematic of a computing device built in accordance with an embodiment.

### EMBODIMENTS OF THE PRESENT DISCLOSURE

Described herein are electronic systems, and more particularly to electronic packages with underfill keep out zones that are protected by a barrier, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, photonics modules may include a photonics integrated circuit (PIC) that is coupled to an electrical integrated circuit (EIC). Since lasers used by the PIC are extremely sensitive, a keep out zone (KOZ) is necessary within the footprint of the PIC and the EIC. Often, the KOZ is towards the center of footprints, away from the edges of either the PIC or the EIC. However, the KOZ needs to be maintained while allowing for an underfill material that provides support to one or more bump fields between the PIC and the EIC. As noted above, capillary underfill (CUF) approaches, non-conductive film (NCF) approaches, and non-conductive paste (NCP) approaches have significant limitations.

Accordingly, embodiments disclosed herein include photonics module architectures that leverage the properties of an NCP with physical barriers. The NCP provides the necessary underfilling properties, while the physical barrier confines the flow of the NCP. It is to be appreciated that such embodiments are distinct from CUF plus barrier applications. In the case of a CUF, the CUF flows easier, and small gaps between the barrier and the PIC allow for significant leakage into the KOZ. On the other hand, the NCP does not flow as well as the CUF, and small gaps (e.g., approximately 10 μm to approximately 20 μm) between the top of the barrier and the bottom of the PIC will not lead to significant leakage into the KOZ.

In some embodiments, the barrier persists into the final structure. In other instances, the barrier is a sacrificial structure and may be removed before assembly of the photonics module is completed. For example, a silicone based barrier may be removed with a targeted etchant, such a fluorine based etchant. However, it is to be appreciated that the edge of the NCP that was in contact with the barrier will maintain the profile of the barrier. As such, a non-vertical edge (e.g., an undercutting edge) may be present in the final structure. Embodiments disclosed herein allow for multiple different barrier topologies (e.g. ring shaped, line shaped, C-shaped, etc.). Examples of the different barrier topologies will be provided in greater detail below.

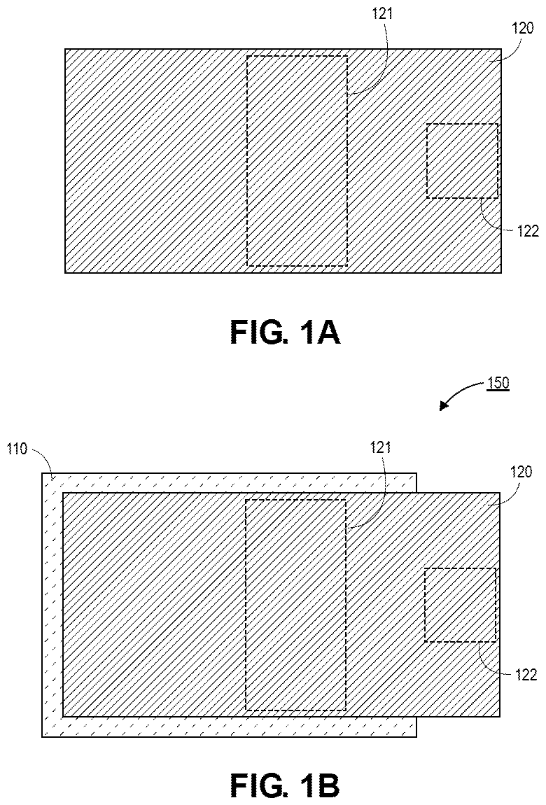

Referring now to FIG. 1A, a plan view illustration of a PIC 120 is shown, in accordance with an embodiment. In an embodiment, the PIC 120 may be any type of PIC 120 that allows for conversion between optical and electrical signals. For example, an electrical signal may be provided as an input and converted to an optical signal through the use of a laser. The PIC 120 may also take an optical signal as an input and convert the optical signal to an electrical signal through the use of an optical sensor. It is to be appreciated that many different PIC 120 architectures are compatible with embodiments disclosed herein. That is to say, embodiments of the PIC 120 are not limited to the structure shown in FIG. 1A or any of the other Figures described herein. The PIC 120 may be referred to as a semiconductor die or, simply, a die.

In an embodiment, the laser and/or the optical sensor may be sensitive to environmental conditions. For example, excess heat can damage or cause malfunctioning of the laser system of the PIC 120. Accordingly, a KOZ 121 is provided under and around the laser. The KOZ 121 is an area below the PIC 120 that will not be covered by an underfill material, or any other material typically found between dies. That is, a void may be provided in the KOZ 121. As shown, the KOZ 121 is formed towards the center of the PIC 120. Though, the KOZ 121 may be at an edge of the PIC 120 in other embodiments. In addition to the KOZ 121 for the laser, a second KOZ 122 may also be provided. The second KOZ 122 may be a region where V-grooves or the like are provided to accommodate optical fibers (not shown).

Referring now to FIG. 1B, a plan view illustration of a photonics module 150 is shown, in accordance with an embodiment. In an embodiment, the photonics module 150 may be a multi-die module. Particularly, the photonics module 150 may include a PIC 120 and an EIC 110. The PIC 120 may be electrically and mechanically coupled to the EIC 110. Additionally, a portion of the PIC 120 may overhang an edge of the EIC 110. The overhanging portion may be the region where the V-grooves are attached (i.e., in the second KOZ 122). In an embodiment, the PIC 120 is electrically coupled to the EIC 110 through interconnects (e.g., solder balls, copper bumps, etc.). For example, bumps (not shown) may be provided to the left and the right of the KOZ 121 in some embodiments. The bumps may be used to transmit electrical signals and power between the PIC 120 and the EIC 110.

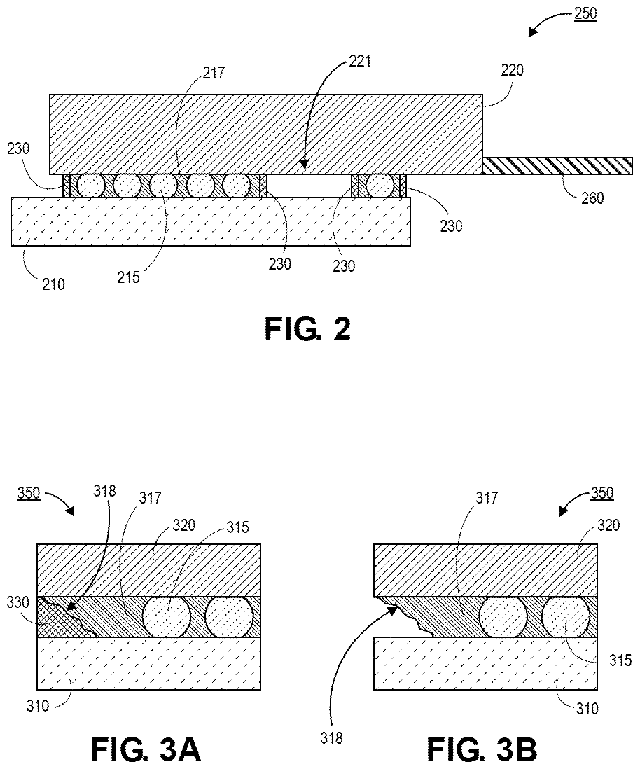

Referring now to FIG. 2, a cross-sectional illustration of a photonics module 250 is shown, in accordance with an embodiment. As shown, bumps 215 provide electrical coupling between the EIC 210 and the PIC 220. While the bumps 215 are illustrated as solder bumps, it is to be appreciated that any interconnect architecture may be provided between the EIC 210 and the PIC 220. For example, copper bump architectures or any other first level interconnect (FLI) architectures may be used to couple the EIC 210 to the PIC 220.

In order to provide mechanical support to the bumps 215, an underfill material 217 is provided around the bumps 215. In a particular embodiment, the underfill material 217 is an NCP. NCP materials are distinct from CUF materials in several ways. One key difference is how the NCP material and the CUF material are applied to a device. An NCP material will typically be dispensed around the bumps prior to thermocompression bonding (TCB), and the bonding process will spread and cure the material. A CUF material, on the other hand, is dispensed using capillary force after the bonding process. NCP materials also have different viscosities than CUF materials. For example, CUF materials generally have lower viscosity than NCP materials before curing.

In order to confine the flow of the underfill material 217, one or more barriers 230 may be provided. The barriers 230 may prevent the underfill material 217 from flowing into the KOZ 221. Pairing the barriers 230 with an NCP underfill material 217 allows for greater tolerances in the height of the barriers 230. As noted above, when the barriers 230 are too tall, the barriers 230 may interfere with the bonding process. Shorter barriers 230 may leave gaps between the top of the barrier 230 and the bottom of the PIC 220. However, due to the higher viscosity of the NCP compared to a CUF, the flow of the NCP is minimized and leakage into the KOZ 221 is minimized. For example, gaps between the barrier 230 and the PIC 220 may be up to approximately 20 μm while still maintaining sufficient integrity of the KOZ 221. As used herein, “approximately” may refer to a range of values within ten percent of the stated value. For example, approximately 20 μm may refer to a range between 18 μm and 22 μm.

In an embodiment, the barriers 230 may be formed from any suitable material. For example, the barriers 230 may comprise silicone, a polymer, or the like. The barriers 230 may be designed to persist into the final structure of the photonics module 250. That is, a cross-section of a finished photonics module 250 may include the presence of the barriers 230. Though, in other embodiments, the barriers 230 may be sacrificial structures, as will be described in greater detail below.

As shown in FIG. 2, a portion of the PIC 220 may overhang an edge of the EIC 210. The overhanging portion of the PIC 220 may be provided in order to accommodate one or more optical fibers 260. The optical fibers 260 may be set into V-grooves (not shown) in the PIC 220. The optical fibers 260 allow for signals to be sent and/or received from devices external to the photonics module 220.

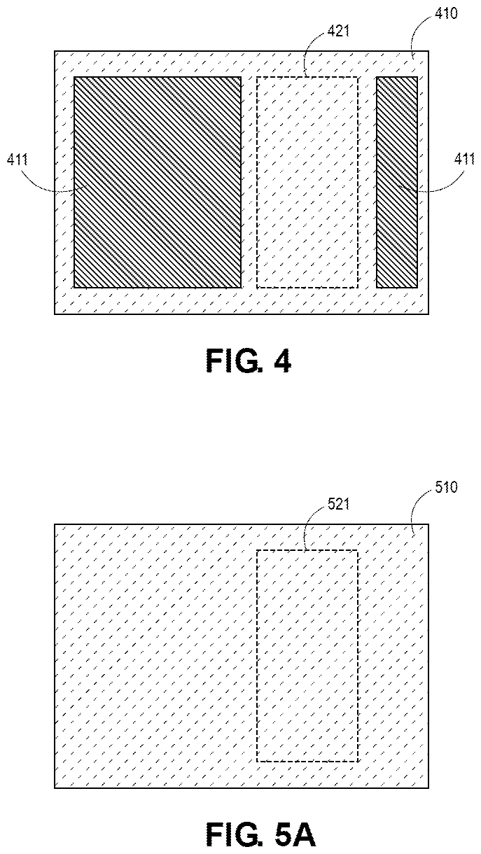

Referring now to FIG. 3A, a zoomed in cross-sectional illustration that more clearly shows a portion of a barrier 330 in a photonics module 350 is shown, in accordance with an embodiment. As shown, an underfill material 317 surrounds the bumps 315 between the PIC 320 and the EIC 310. One of the edges of the barrier 330 is shown in FIG. 3A. As shown, the underfill material 317 conforms to the edge of the barrier 330. As such, an edge 318 of the underfill material 317 may be non-vertical. In the particular embodiment shown, the edge 318 is tapered so that the underfill material 317 is undercut. In other embodiments, the barrier 330 may have a more traditional fillet shape to which the underfill material 317 conforms. In an embodiment, the edge 318 may be the edge that faces the KOZ (not shown). For example, the KOZ may be provided to the left of the barrier 330, as shown in FIG. 3A.

Referring now to FIG. 3B, a zoomed in cross-sectional illustration of the photonics module 350 is shown, in accordance with an additional embodiment. The photonics module 350 in FIG. 3B may be substantially similar to the photonics module 350 in FIG. 3A, with the exception of the removal of the barrier 330. For example, the barrier 330 may be removed after the underfill material 317 is cured (e.g., during the TCB process). Since the underfill material 317 is cured while the barrier 330 is in place, the edge 318 of the underfill material 317 maintains the non-vertical profile after the barrier 330 is removed. As shown, the edge 318 undercuts the underfill material 317. The void to the left of the edge 318 may be part of the KOZ in some embodiments. In an embodiment, the barrier 330 may be removed with any suitable etching chemistry that is selective to the material of the barrier 330. For example, in the case of a silicone barrier 330, a fluorine based chemistry may be used to remove the barrier 330.

Referring now to FIG. 4, a plan view illustration of the EIC 410 is shown, in accordance with an embodiment. The EIC 410 may include any type of semiconductor die that is configured to operate in the electrical regime. That is, embodiments are not limited to any particular EIC architecture. In some instances the EIC 410 may simply be referred to as a semiconductor die or, simply, a die. In an embodiment, the EIC 410 may include a KOZ 421. The KOZ 421 on the EIC 410 may be aligned with the KOZ provided in an overlying PIC (not shown). As shown, the KOZ 421 is set away from the edge of the EIC 410. More particularly, bump fields 411 may be provided to the left and to the right of the KOZ 421, as viewed in FIG. 4. The bump fields 411 may be locations where interconnects are provided that will couple the EIC 410 with the overlying PIC.

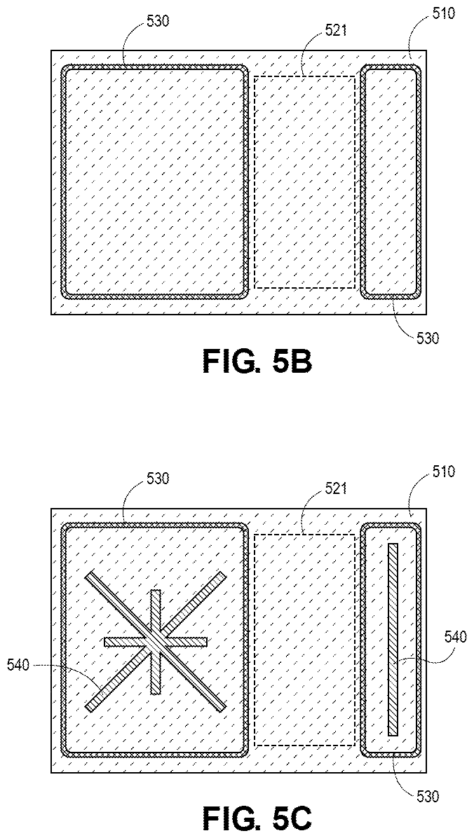

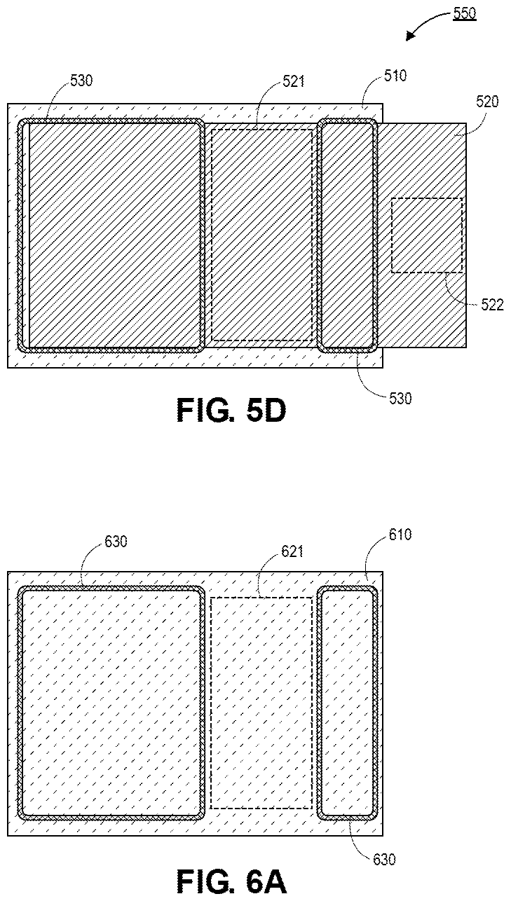

Referring now to FIGS. 5A-5D, a series of plan view illustrations depicting a process for assembling a photonics module 550 is shown, in accordance with an embodiment. In the illustrated embodiment, a ring type barrier layer 530 is used. Though, it is to be appreciated that any of the barrier topologies described in greater detail below can be used in order to form a similar photonics module 550.

Referring now to FIG. 5A, a plan view illustration of an EIC 510 is shown, in accordance with an embodiment. In an embodiment the EIC 510 may include a KOZ 521. The KOZ 521 may be aligned with the KOZ of an overlying PIC (which will be mounted to the EIC 510 in a subsequent processing operation). In an embodiment, the KOZ 521 may be set back from the left edge and the right edge of the EIC 510, as viewed in FIG. 5A. This allows for bumps to be provided on either side of the KOZ 521. For example, bump fields similar to those shown in FIG. 4 may be provided on the EIC 510.

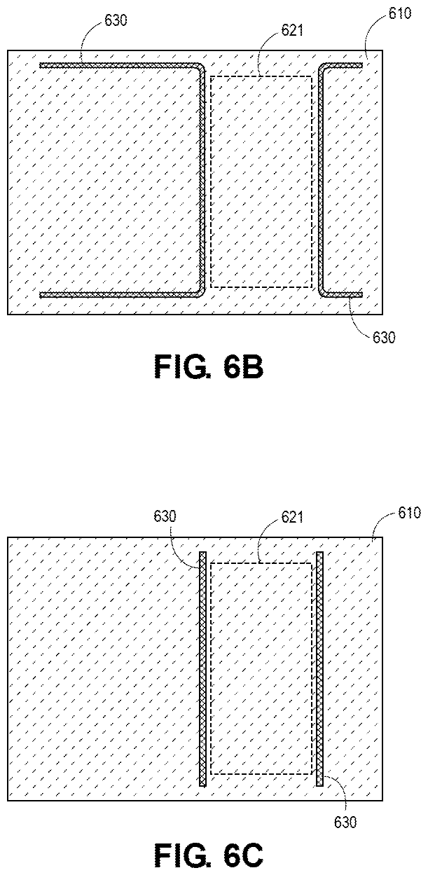

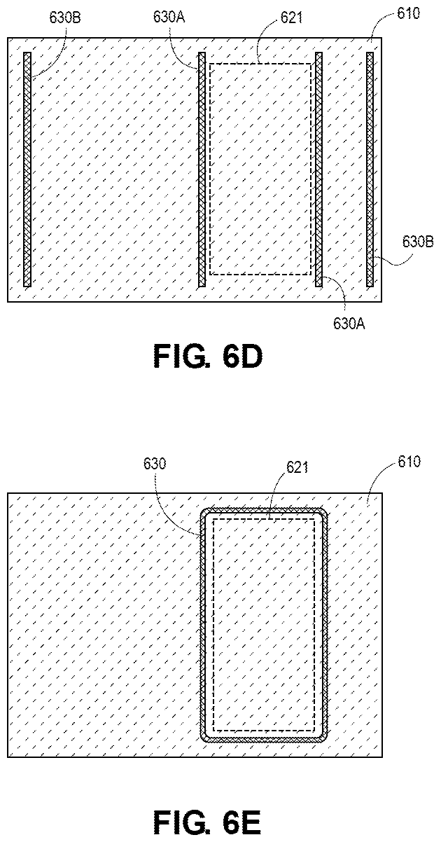

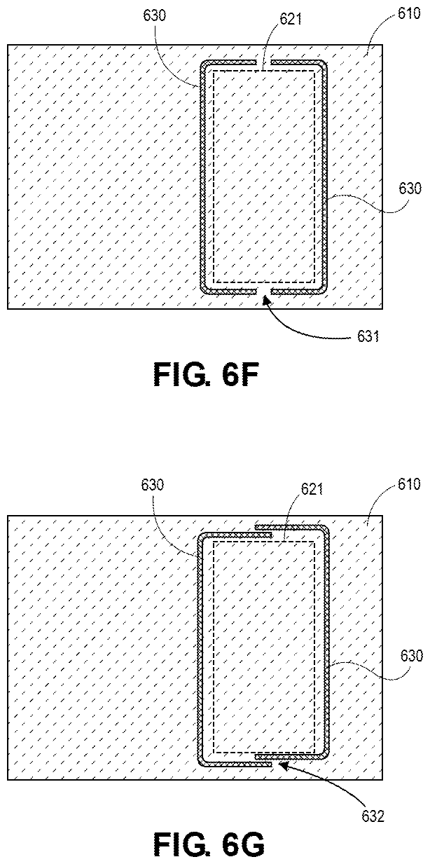

Referring now to FIG. 5B, a plan view illustration of the EIC 510 after the formation of a barrier layer 530 is shown, in accordance with an embodiment. In an embodiment, the barrier layer 530 may be a ring structure. More particularly, a first ring barrier layer 530 may be provided on one side of the KOZ 521 and a second ring barrier layer 530 may be provided on the opposite side of the KOZ 521. In an embodiment, the barrier layers 530 may have widths that are approximately 100 μm or greater. For example, the widths of the barrier layers 530 may be approximately 500 μm in some embodiments. While two distinct barrier layers 530 (each with a ring structure) are shown in FIG. 5B, it is to be appreciated that any barrier topology may be used. For example, alternative topologies are illustrated in FIGS. 6A-6G.

The barrier layers 530 may comprise any suitable material that can prevent the flow of an underfill material into the KOZ 521. For example, the barrier layers 530 may comprise silicone, a polymer, or the like. In an embodiment, the barrier layers 530 may be applied with a printing process. For example, a contact dispensing process that utilizes a needle for precise control of the deposition of the barrier layers 530 may be used in some embodiments.

Referring now to FIG. 5C, a plan view illustration of the EIC 510 after an underfill 540 dispense operation is shown, in accordance with an embodiment. As shown, the underfill 540 may be dispensed with any suitable pattern. For example, on the left side of the KOZ 521, a star dispense pattern is used, and on the right side of the KOZ 521 a line dispense pattern is used. In an embodiment, the shot weight of the underfill 540 may be carefully controlled in order to ensure complete spreading within the barriers 530. In an embodiment, the underfill 540 may be an NCP.

Referring now to FIG. 5D, a plan view illustration of a photonics module 550 is shown, in accordance with an embodiment. In an embodiment, the photonics module 550 may include the EIC 510 with a PIC 520 mounted to the EIC 510. For example, a TCB bonding process may be used to bond the PIC 520 to the EIC 510 in some embodiments. In the illustration, the barrier layers 530 are shown in order to clearly see their positioning in FIG. 5D. However, it is to be appreciated that the barrier layers 530 will instead be located between the EIC 510 and the PIC 520. Additionally, the TCB bonding process will result in the spreading and curing of the NCP 540.

In an embodiment, the PIC 520 may include an overhang that extends out past an edge of the EIC 510. The overhang portion may include another KOZ 522. The second KOZ 522 may be used to keep the PIC 520 clear so optical fibers (not shown) can be inserted into V-grooves of the PIC 520.

In an embodiment, the assembly of the PIC 520 to the EIC 510 may be complete at this point of the process flow. However, in other embodiments, the barrier layers 530 may subsequently be removed. For example, in the case of silicone barrier layers 530, an etching chemistry comprising fluorine may be used to remove the barrier layers 530. When the barrier layers 530 are removed, the underfill 540 will maintain a non-vertical profile, similar to embodiments described above with respect to FIG. 3B.

Referring now to FIGS. 6A-6G, a series of plan view illustrations depicting different of barrier 630 configurations is shown, in accordance with an embodiment. The different barrier 630 configurations shown in FIGS. 6A-6G may provide protection to the KOZ 621. Further, while specific barrier 630 topologies are shown in FIGS. 6A-6G, it is to be appreciated that embodiments are not limited to such architectures. That is, any conceivable architecture that protects the KOZ 621 may be used in accordance with embodiments described herein.

Referring now to FIG. 6A, a plan view illustration of an EIC 610 is shown, in accordance with an embodiment. In an embodiment, the EIC 610 may comprise a first ring barrier 630 to the left of the KOZ 621 and a second ring barrier 630 to the right of the KOZ 621. The ring barriers 630 may have widths that are approximately 100 μm or greater. For example, the widths may be up to approximately 500 μm in some embodiments. In an embodiment, the ring barriers provide complete enclosures to confine the flow of underfill (not shown) in all directions. That is, the underfill will not leak or ooze out any side of the EIC 610.

Referring now to FIG. 6B, a plan view illustration of an EIC 610 is shown, in accordance with an additional embodiment. In an embodiment, the barriers 630 may have a C-shaped configuration. That is, each barrier 630 may include a line adjacent to the KOZ 621 with a pair of arms extending away from the KOZ 621. The C-shaped barriers 630 in FIG. 6B may be facing away from each other. That is, the opening of the barriers 630 face opposite directions from each other. Such an embodiment may be beneficial when the excess underfill is dispensed, and there needs to be an escape path to accommodate the excess. The barriers 630 may have widths that are approximately 100 μm or greater.

Referring now to FIG. 6C, a plan view illustration of an EIC 610 is shown, in accordance with an additional embodiment. In an embodiment, the barriers 630 may be line shaped. That is, vertical lines may be provided adjacent to each side of the KOZ 621. Such an embodiment provides freedom for the underfill to overflow without getting into the KOZ 621. The barriers 630 may have widths that are approximately 100 μm or greater.

Referring now to FIG. 6D, a plan view illustration of an EIC 610 is shown, in accordance with an additional embodiment. In an embodiment, the EIC 610 may include a pair of barriers 630A and 630B on each side of the KOZ 621. The barriers 630A may be adjacent to the KOZ 621, and the barriers 630B may be on opposite edges of the EIC 610. Such an embodiment, can be used to confine the flow of excess underfill so that it only oozes out the top and bottom edges (as viewed in FIG. 6D). The barriers 630A and 630B may have widths that are approximately 100 μm or greater

Referring now to FIG. 6E, a plan view illustration of an EIC 610 is shown, in accordance with an additional embodiment. In an embodiment, the EIC 610 may comprise a ring shaped barrier 630. However, instead of being formed around the bump field, as shown in FIG. 6A, the barrier 630 in FIG. 6E is formed around the KOZ 621. This provides protection to the KOZ 621 along all four sides of the KOZ 621. The barrier 630 may have a width that is approximately 100 μm or greater.

Referring now to FIG. 6F, a plan view illustration of an EIC 610 is shown, in accordance with an additional embodiment. In an embodiment, the EIC 610 may comprise a pair of C-shaped barriers 630. The C-shaped barriers 630 may be oriented so that they face each other. That is, the open end of each barrier 630 faces the other barrier 630. The two barriers 630 may wrap around the perimeter of the KOZ 621. However, there may be a gap 631 between the arms of each of the barriers 630. The gap 631 may function as a pressure release feature in order to protect the components within the KOZ 621.

Referring now to FIG. 6G, a cross-sectional illustration of an EIC 610 is shown, in accordance with an additional embodiment. In an embodiment the EIC 610 may comprise a pair of barriers 630 that are C-shaped. The arms of the barriers 630 may at least partially overlap each other. For example, the two barriers 630 may be offset from each other to allow the arms to pass the opposing arms. In an embodiment, a gap 632 may be provided between opposing arms. The gap 632 may be used as a pressure relief gap in order to protect the components within the KOZ 621.

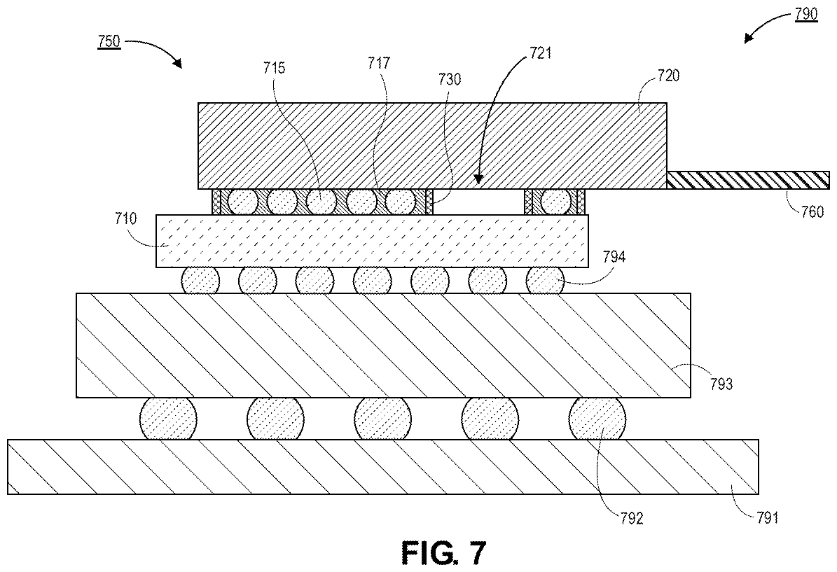

Referring now to FIG. 7, a cross-sectional illustration of an electronic system 790 is shown, in accordance with an embodiment. In an embodiment, the electronic system 790 comprises a board 791, such as a printed circuit board (PCB). The board 791 may be coupled to a package substrate 793 by interconnects 792. The interconnects 792 may be solder balls, sockets, or the like. In an embodiment, a photonics module 750 may be coupled to the package substrate 793 through interconnects 794.

In an embodiment, the photonics module 750 may comprise a first die 710, such as an EIC. The first die 710 may be electrically coupled to a second die 720, such as a PIC. Interconnects 715, such as solder, copper bumps, or any other FLI architecture may be used to couple the first die 710 to the second die 720. In an embodiment, the interconnects 715 may be surrounded by an underfill 717, such as an NCP. The underfill 717 may be prevented from flowing into a KOZ 721 by barriers 730. A portion of the second die 720 may overhang an edge of the first die 710, and an optical fiber 760 may be attached to a V-groove (not shown) in the second die 720.

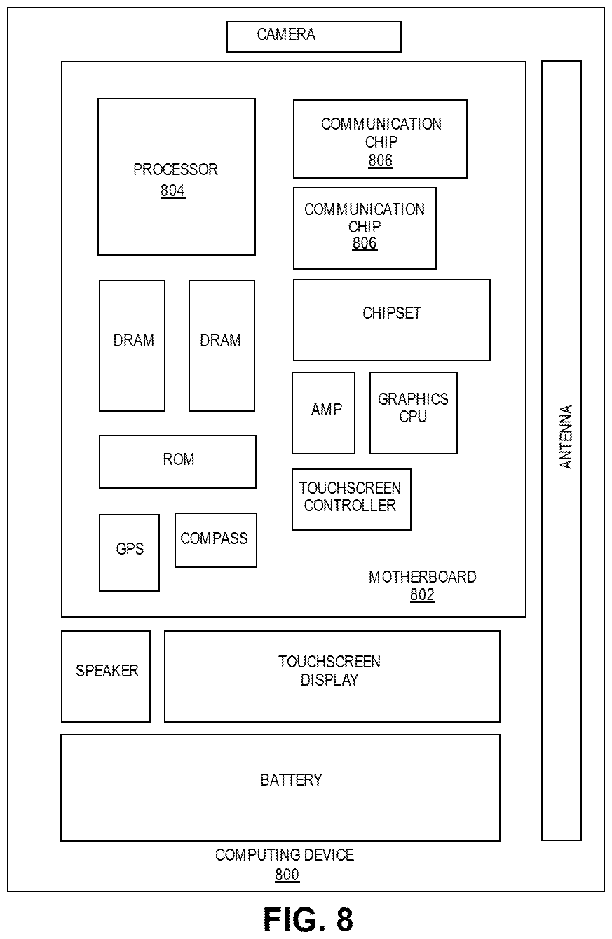

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of a photonics module that includes a PIC and an EIC with a KOZ that is protected from NCP underfill by a barrier, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of a photonics module that includes a PIC and an EIC with a KOZ that is protected from NCP underfill by a barrier, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a multi-die module, comprising: a first die; a second die coupled to the first die, wherein the second die comprises a keep out zone that at least partially overlaps the first die; and an underfill between the first die and the second die, wherein the underfill is entirely outside the keep out zone, and wherein an edge of the underfill facing the keep out zone is non-vertical.

Example 2: the multi-die module of Example 1, further comprising: a barrier contacting the underfill, wherein the edge of the underfill facing the keep out zone is in direct contact with the barrier.

Example 3: the multi-die module of Example 2, wherein the barrier comprises silicone.

Example 4: the multi-die module of Example 2 or Example 3, wherein the barrier is a ring shaped feature.

Example 5: the multi-die module of Example 4, wherein the ring shaped feature surrounds the keep out zone.

Example 6: the multi-die module of Example 2 or Example 3, wherein the barrier is C-shaped.

Example 7: the multi-die module of Example 6, further comprising a second C-shaped barrier, wherein the barrier is on a first side of the keep out zone and the second C-shaped barrier is on a second side of the keep out zone that is opposite from the first side.

Example 8: the multi-die module of Example 7, wherein the barrier is offset from the second C-shaped barrier, and wherein arms of the barrier overlap arms of the second C-shaped barrier.

Example 9: the multi-die module of Example 2 or Example 3, wherein the barrier is a line.

Example 10: the multi-die module of Examples 2-9, wherein the barrier has a width that is approximately 100 μm or greater.

Example 11: the multi-die module of Examples 1-10, wherein the first die is an electrical integrated circuit (EIC), and wherein the second die is a photonics integrated circuit (PIC).

Example 12: the multi-die module of Example 11, wherein a laser is provided in the keep out zone.

Example 13: a multi-die module, comprising: a first die; a second die coupled to the first die; and an underfill between the first die and the second die, wherein an edge of the underfill within a footprint of the first die and the second die is non-vertical.

Example 14: the multi-die module of claim 13, wherein the non-vertical edge is oriented to form an undercut.

Example 15: the multi-die module of Example 13 or Example 14, further comprising: a barrier adjacent to and contacting the edge of the underfill.

Example 16: the multi-die module of Examples 13-15, wherein the first die is an electrical integrated circuit (EIC), and wherein the second die is a photonics integrated circuit (PIC).

Example 17: the multi-die module of Examples 13-16, wherein the edge of the underfill faces a keep out zone.

Example 18: an electronic system, comprising: a board; a package substrate coupled to the board; and a multi-die module coupled to the package substrate, wherein the multi-die module comprises: a first die; a second die coupled to the first die; an underfill between the first die and the second die; and a barrier between the first die and the second die, wherein the barrier is between the underfill and a keep out zone.

Example 19: the electronic system of Example 18, wherein the first die is an electrical integrated circuit (EIC), and wherein the second die is photonics integrated circuit (PIC).

Example 20: the electronic system of Example 18 or Example 19, wherein the electronic system is part of a personal computer, a server, a mobile device, a tablet, or an automobile.

What is claimed is:

1. A multi-die module, comprising:
a first die;
a second die coupled to the first die, wherein the second die comprises a keep out zone that at least partially overlaps the first die; and
an underfill between the first die and the second die, wherein the underfill is entirely outside the keep out zone, and wherein an edge of the underfill facing the keep out zone is non-vertical.

2. The multi-die module of claim 1, further comprising:
a barrier contacting the underfill, wherein the edge of the underfill facing the keep out zone is in direct contact with the barrier.

3. The multi-die module of claim 2, wherein the barrier comprises silicone.

4. The multi-die module of claim 2, wherein the barrier is a ring shaped feature.

5. The multi-die module of claim 4, wherein the ring shaped feature surrounds the keep out zone.

6. The multi-die module of claim 2, wherein the barrier is C-shaped.

7. The multi-die module of claim 6, further comprising a second C-shaped barrier, wherein the barrier is on a first side of the keep out zone and the second C-shaped barrier is on a second side of the keep out zone that is opposite from the first side.

8. The multi-die module of claim 7, wherein the barrier is offset from the second C-shaped barrier, and wherein arms of the barrier overlap arms of the second C-shaped barrier.

9. The multi-die module of claim 2, wherein the barrier is a line.

10. The multi-die module of claim 2, wherein the barrier has a width that is approximately 100 μm or greater.

11. The multi-die module of claim 1, wherein the first die is an electrical integrated circuit (EIC), and wherein the second die is a photonics integrated circuit (PIC).

12. The multi-die module of claim 11, wherein a laser is provided in the keep out zone.

13. A multi-die module, comprising:
a first die;
a second die coupled to the first die; and
an underfill between the first die and the second die, wherein an edge of the underfill within a footprint of the first die and the second die is non-vertical.

14. The multi-die module of claim 13, wherein the non-vertical edge is oriented to form an undercut.

15. The multi-die module of claim 13, further comprising:
a barrier adjacent to and contacting the edge of the underfill.

16. The multi-die module of claim 13, wherein the first die is an electrical integrated circuit (EIC), and wherein the second die is a photonics integrated circuit (PIC).

17. The multi-die module of claim 13, wherein the edge of the underfill faces a keep out zone.

18. An electronic system, comprising:
a board;
a package substrate coupled to the board; and
a multi-die module coupled to the package substrate, wherein the multi-die module comprises:
a first die;
a second die coupled to the first die;
an underfill between the first die and the second die; and
a barrier between the first die and the second die, wherein the barrier is between the underfill and a keep out zone.

19. The electronic system of claim 18, wherein the first die is an electrical integrated circuit (EIC), and wherein the second die is photonics integrated circuit (PIC).

20. The electronic system of claim 18, wherein the electronic system is part of a personal computer, a server, a mobile device, a tablet, or an automobile.
